(19) United States
(12) Patent Application Publication
(10) Pub. No.: US 2010/0259875 A1
(43) Pub. Date: Oct. 14, 2010

(54) BATTERY COVER ASSEMBLY FOR PORTABLE ELECTRONIC DEVICE

(75) Inventors: MU-WEN YANG, Taipei (TW); CHIH-CHIANG CHANG, Taipei (TW)

Correspondence Address: Altis Law Group, Inc.;ATTN: Steven Reiss, 288 SOUTH MAYO AVENUE, CITY OF INDUSTRY, CA, 91789, US

(73) Assignee: FIH (HONG KONG) LIMITED, Kowloon (HK)

(21) Appl. No.: 12/649,561

(22) Filed: Dec. 30, 2009

(30) Foreign Application Priority Data
Apr. 13, 2009 (CN) 200910301520.5

(51) Int. Cl. H05K 5/03

(52) U.S. Cl. 361/679.01

(57) ABSTRACT

A battery cover assembly for a portable electronic device includes a housing, a battery cover, and a pivot member. The battery cover forms an engaging portion arranged at a circle. The pivotal member defines a ring groove receiving the engaging portion. The battery cover rotatably connects the battery cover to the housing.

### CROSS-REFERENCE TO RELATED APPLICATIONS

This application is related to two co-pending U.S. Patent Applications (Attorney Docket Nos. US26753 and US26752), both entitled “BATTERY COVER ASSEMBLY FOR PORTABLE ELECTRONIC DEVICE”, by MU-WEN YANG et al. Such applications have the same assignee as the instant application and have been concurrently filed herewith. The disclosures of the above identified applications are incorporated herein by reference.

### BACKGROUND

1. Technical Field

The present disclosure generally relates to battery cover assemblies and, particularly, to a battery cover assembly for use in a portable electronic device.

2. Description of Related Art

Batteries are widely used in portable electronic devices, such as personal digital assistants (PDAs), mobile phones, and so on. Conventional batteries are attachably received in the electronic device, and battery covers are designed to connect with housings of the electronic devices to package the batteries. The batteries have to be replaced by opening the battery covers when, for example, the batteries are damaged and/or dead (i.e. no longer rechargeable).

Although battery cover assemblies may be simple, the engagement between the battery cover and the housing of the mobile phone can be too firm to be easily manually detached from each other.

Therefore, there is room for improvement within the art.

### BRIEF DESCRIPTION OF THE DRAWINGS

Many aspects of the battery cover assembly can be better understood with reference to the following drawings. The components in the drawings are not necessarily drawn to scale, the emphasis instead being placed upon clearly illustrating the principles of the battery cover assembly. Moreover, in the drawings, like reference numerals designate corresponding parts throughout the several views, in which:

FIG. 1 is an isometric view of a portable electronic device employing a battery cover assembly;

FIG. 2 is an exploded, isometric view of the portable electronic device in accordance with a first exemplary embodiment;

FIG. 3 is similar to FIG. 2, but viewed from another aspect;

FIG. 4 is a cross sectional view of FIG. 1 taken along line IV-IV;

FIG. 5 is an isometric view showing the battery cover open;

FIG. 6 is an exploded, isometric view of the portable electronic device in accordance with a second exemplary embodiment;

FIG. 7 is similar to FIG. 6, but viewed from another aspect; and

FIG. 8 is an exploded, isometric view of the portable electronic device in accordance with a third exemplary embodiment.

### DETAILED DESCRIPTION

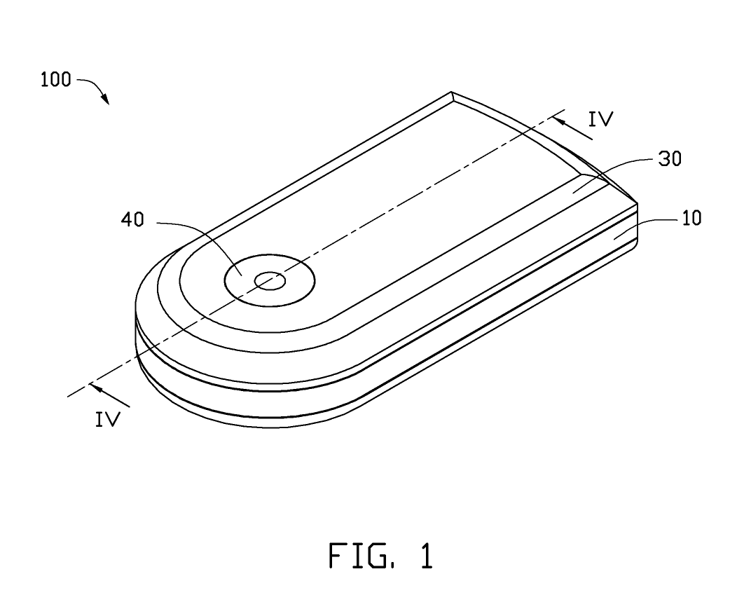

FIG. 1 shows a portable electronic device 100, such as a mobile phone, employing a battery cover assembly. The mobile phone 100 is an exemplary application, for the purposes of describing details of a battery cover assembly of a first exemplary embodiment. The battery cover assembly incorporates a housing 10, a pivot member 20, a battery cover 30, and a cover member 40. The pivot member 20 rotatably connects the battery cover 30 to the housing 10.

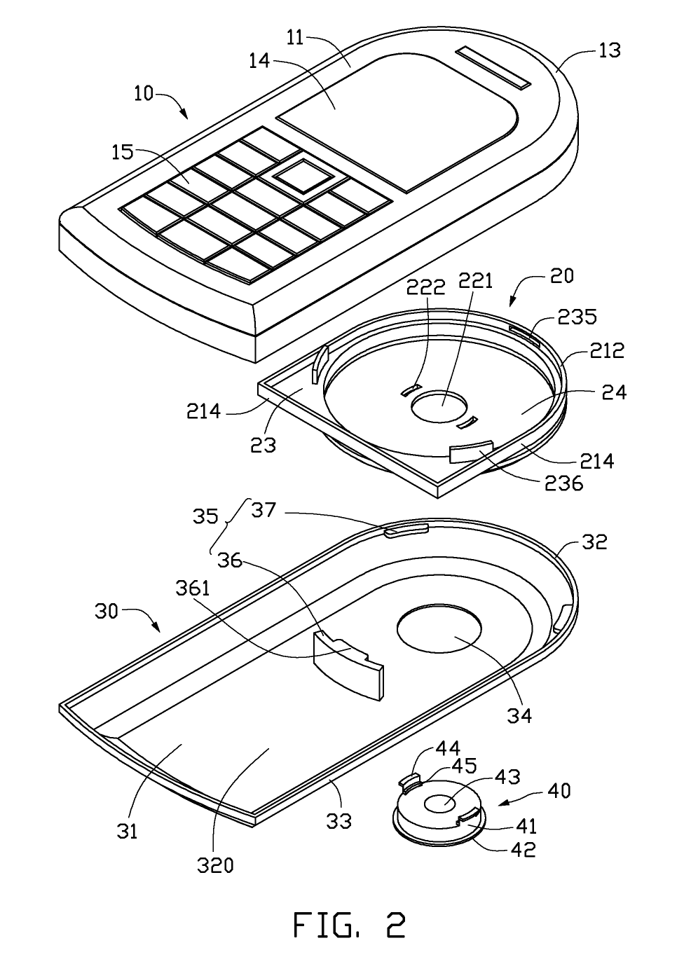

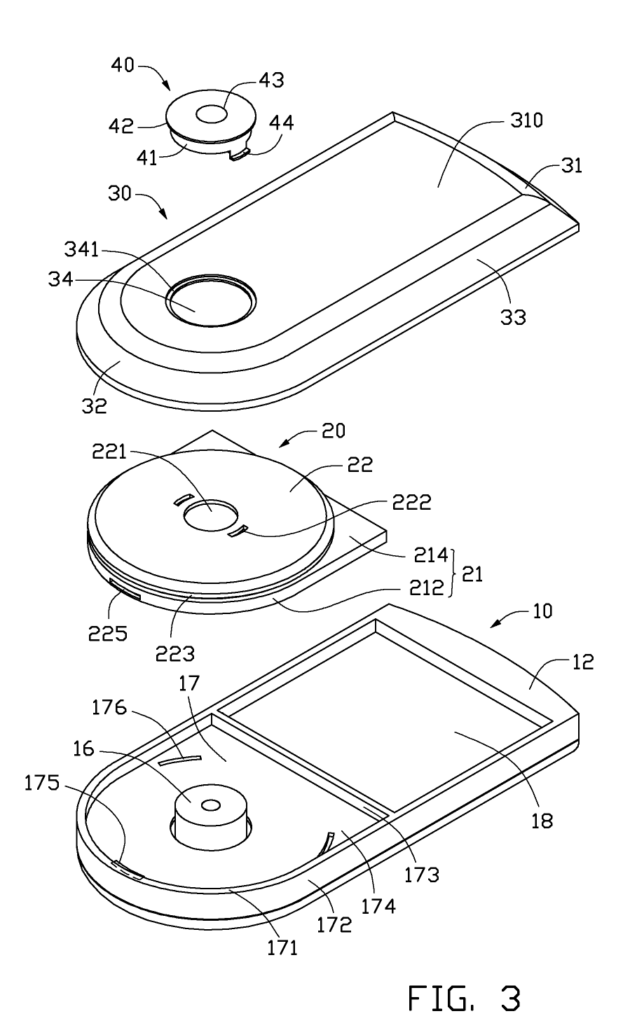

Referring to FIGS. 2 and 3, the housing 10 includes a main body 13. The main body 13 includes a first surface 11 and a second surface 12. A display 14 and a keypad 15 are formed on the first surface 11. The second surface 12 of the main body 13 includes a bottom wall 174, a semi-circular wall 171, and two sidewalls 172. A beam 173 divides the main body 13 into a groove 17 receiving the pivot member 20 and a cavity 18 receiving a battery. A camera module 16 is disposed in the bottom wall 174, and is positioned at a center of the semi-circular wall 171. The bottom wall 174 in the groove 17 defines two latching slots 176. Each latching slot 76 is substantially arcuate. The semi-circular wall 171 perpendicularly forms a latching plate 175. The latching slots 176 and the latching plate 175 are substantially arranged in a circle surrounding the camera module 16.

The pivot member 20 includes a base plate 21 and a rotatable disk 22 formed on the base plate 21. The base plate 21 includes a semi-circular portion 212 tangentially connected a rectangular portion 214. The rotatable disk 22 is coaxial with the semi-circular portion 212. The rotatable disk 22 defines a through hole 221 at a center thereof and two notches 222 at two sides of the through hole 221. A ring groove 223 is defined in an outermost circumferential edge of the rotatable disk 22 toward the base plate 21. The semi-circular portion 212 defines a cutout 235 engagable with the latching plate 175. The base plate 21 defines a receiving cavity 23 and a circular cavity 24 opposite to the rotatable disk 22. The base plate 21 has two arcuate ribs 236 formed adjacent to and parallel with a circumference of the circular cavity 24. The ribs 236 are received in the latching slots 176.

The battery cover 30 includes a back wall 31, a semi-circular edge 32, and two sides edges 33. The back wall 31 includes an outer surface 310 and an inner surface 320. The inner surface 320 perpendicularly extends an arcuate block 361. The arcuate block 361 extends a tab 36. The semi-circular edge 33 extends two spaced tabs 342. The tabs 36, 342 constitute an engaging portion 35 configured for engaging in the ring groove 223 of the rotatable disk 22. The outer surface 310 defines a stepped hole 34 and forms a stepped surface 341.

The cover member 40 can be made of plastics, and includes a main section 41. A flange 42 extends from one end of the main section 41. The flange 42 may abut against the stepped surface 341. The main section 41 includes a light transmissive portion 43. Two hooks 44 are disposed at two sides of the main section 41 opposite to the flange 42, and may be received in the notches 222 of the rotatable disk 22. Each hook 44 forms a latching block 45.

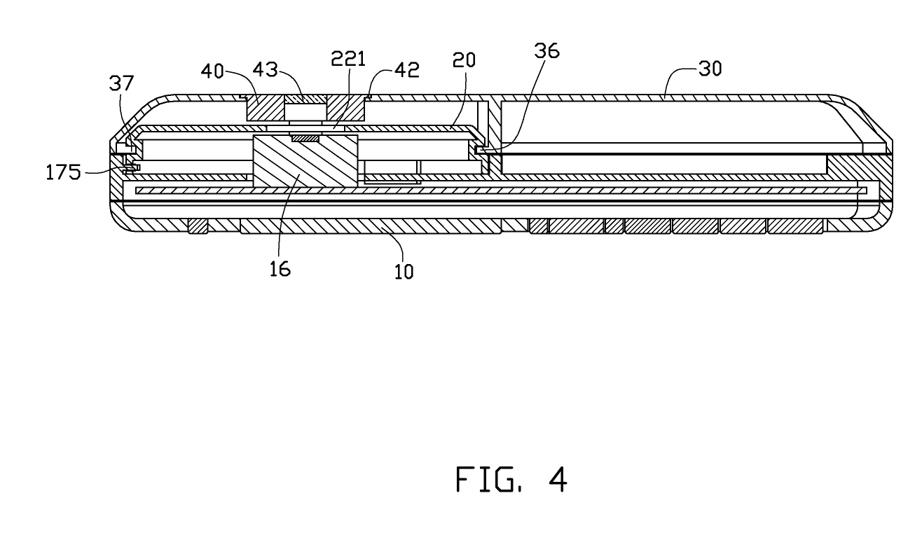

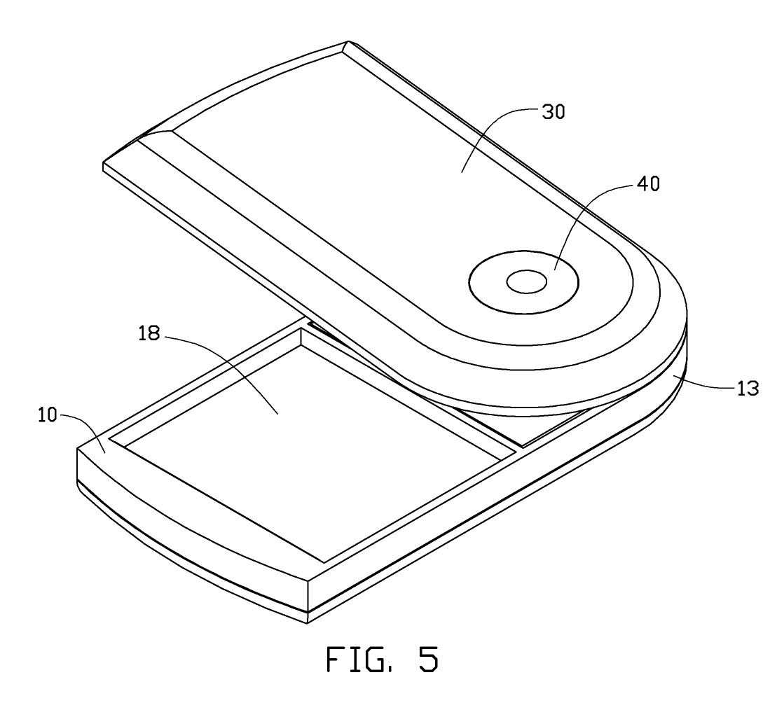

During assembly of the battery cover assembly, referring to FIGS. 4 and 5, firstly, the base plate 21 is received in the groove 17, and the ribs 236 are latched in the latching slots 176. The latching plate 175 is latched in the cutout 235 to cause the pivot member 20 to be fixed to the housing 10. Then, the tabs 37, 361 of the battery cover 30 are received in the ring groove 223 of the pivot member 10. Thus, the battery cover 30 is rotatably connected to the housing 10. The battery cover 30 may be fixed to any position by friction between the tabs 37, 361 and the ring groove 223. Finally, the main section 41 of the cover member 40 is received in the stepped hole 34, and the latching blocks 45 resist the rotatable disk 22. The two hooks 44 are latched in the notches 222. Thus, the cover member 40 is fixed to the pivot member 20, and is rotatably connected to the battery cover 30.

When the battery cover 30 is opened, the user needs only to apply a force larger than a friction force between the engaging portion 35 and the groove 223 to rotate the battery cover 30. The battery cover 30 is rotated to the housing 10 around the pivot member 20 and the cover member 40. Thus, the battery cover 30 may be rotated to a predetermined position.

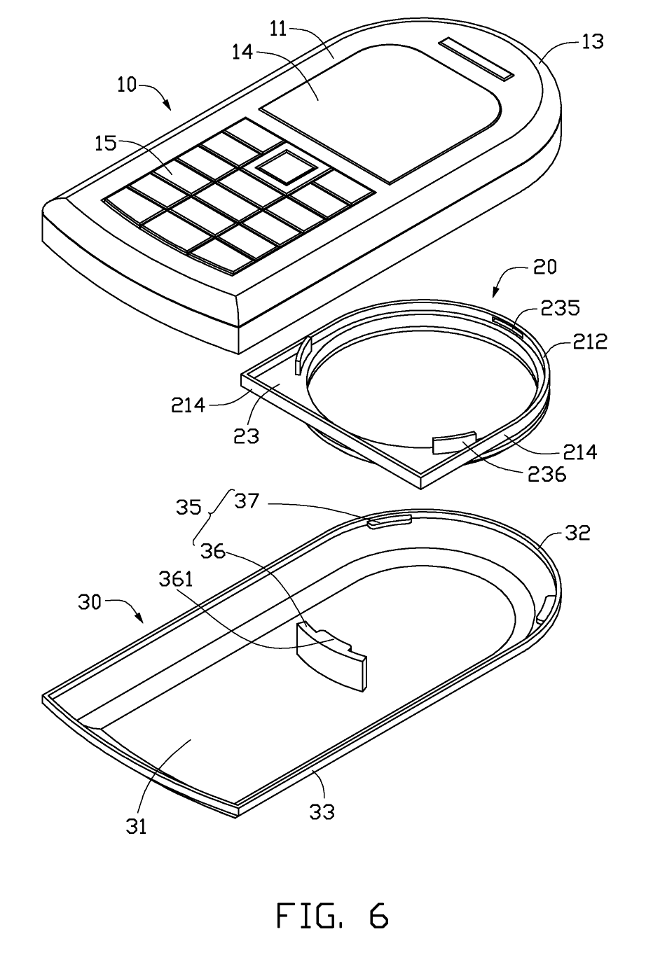

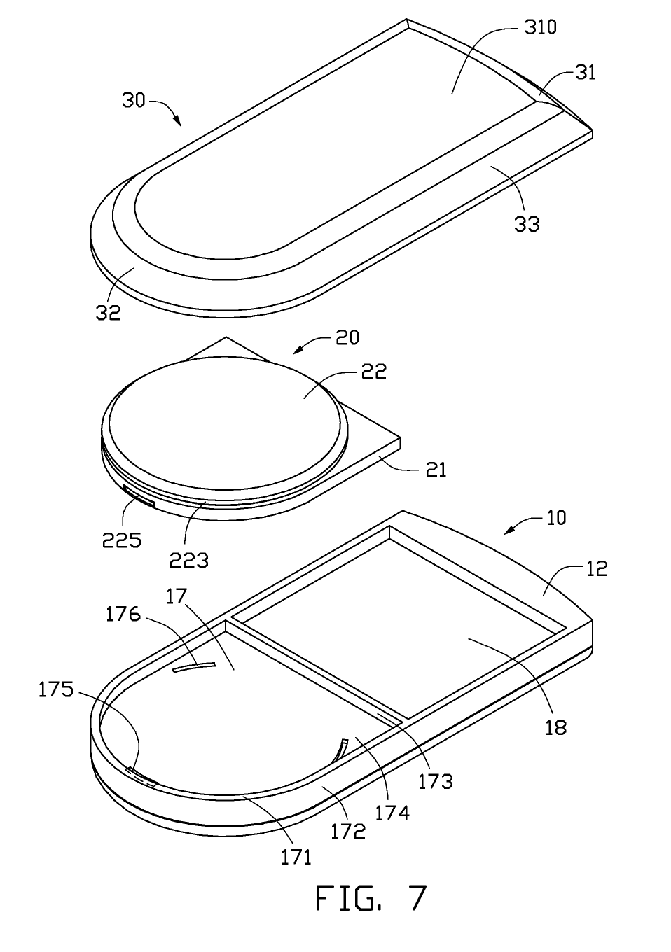

Referring to FIGS. 6 and 7, the cover member 40 may be omitted. Accordingly, the lens module 16, the hole 221 and the stepped hole 34 may be omitted. The battery cover 30 is rotated to the housing 10 only around the pivot member 20.

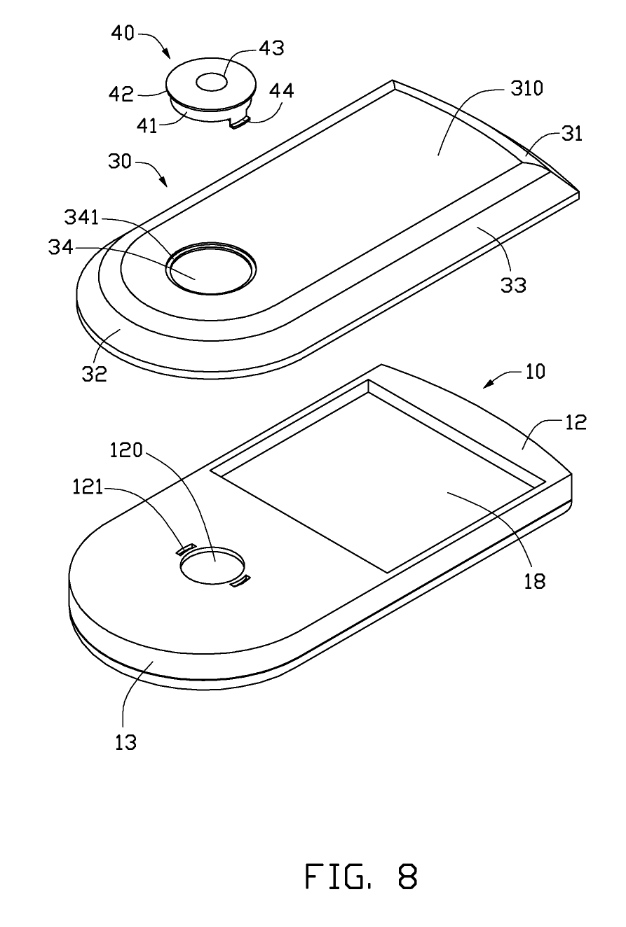

Referring to FIG. 8, the pivot member 20 may be omitted. Accordingly, the corresponding structure of the housing 10 and the battery cover 30 may be omitted. The battery cover 30 is rotated to the housing 10 around the cover member 40.

As described above, the exemplary embodiment provides a battery cover assembly for portable electronic devices, such as mobile phones. The battery cover of the battery cover assembly can be easily opened. This rotatable removal step makes the operation of the device more user-friendly.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A battery cover assembly for a portable electronic device, the battery cover assembly comprising:
a housing;
a battery cover forming an engaging portion arranged in a circle; and
a pivotal member defining a ring groove receiving the engaging portion, the battery cover rotatably connecting the battery cover to the housing.

2. The battery cover assembly as claimed in claim 1, wherein the pivot member includes a base plate and a rotatable disk formed on the base plate, and the ring groove is defined at the rotatable disk toward the base plate.

3. The battery cover assembly as claimed in claim 2, wherein the base plate includes a semi-circular portion and a rectangular portion tangentially connected each other, and the rotatable disk is coaxial with the semi-circular portion, the base plate defines two ribs, and the housing defines two latching slots receiving the ribs.

4. The battery cover assembly as claimed in claim 3, wherein the semi-circular portion defines a cutout, the housing extends a latching plate engagable with the cutout.

5. The battery cover assembly as claimed in claim 1, wherein the housing includes a main body, the main body includes a bottom wall, a semi-circular wall, and two sidewalls, a beam divides the main body into a groove for receiving the pivot member and a cavity for receiving a battery.

6. The battery cover assembly as claimed in claim 5, wherein a camera module is disposed in the bottom wall, and is positioned at a center of the semi-circular wall.

7. The battery cover assembly as claimed in claim 5, wherein the bottom wall defines two latching slots, the latching slots are arranged at a circle, and the semi-circular wall forms a latching plate engaging in the ring groove.

8. The battery cover assembly as claimed in claim 1, wherein the engaging portion includes three tabs, the battery cover includes a back wall, a semi-circular edge, and two sides edges, the back wall perpendicularly extends an arcuate block, one of the three tabs extends from the arcuate block, and two of the three tabs extend from the semi-circular edge.

9. The battery cover assembly as claimed in claim 1, further comprising a cover member, wherein the cover member includes a main section, and a flange extends from one end of the main section, two hooks are disposed at two sides of the main section opposite to the flange, and the pivot member defines two notches receiving the hooks.

10. A portable electronic device comprising:
a housing defining a groove and a plurality of latching slots;
a pivot member received in the groove, the pivot member defining a ring groove and forming a plurality of ribs received in the latching slots; and
a battery cover forming a plurality of tabs rotatably received in the ring groove.

11. The portable electronic device as claimed in claim 10, wherein the pivot member includes a base plate and a rotatable disk formed on the base plate, and the base plate is received in the groove.

12. The portable electronic device as claimed in claim 11, wherein the base plate includes a semi-circular portion and a rectangular portion tangentially connected each other, and the rotatable disk is coaxial with the semi-circular portion.

13. The portable electronic device as claimed in claim 12, wherein, the base plate defines two ribs, and the housing defines two latching slots receiving the ribs.

14. The portable electronic device as claimed in claim 11, wherein the semi-circular portion defines a cutout, the housing extends a latching plate engagable with the cutout.

15. The portable electronic device as claimed in claim 11, the battery cover includes a back wall, a semi-circular edge, and two sides edges, the back wall perpendicularly extends an arcuate block, the number of the tabs is three, one of the three tabs extends from the arcuate block, and two of the three tabs extend from the semi-circular edge.

16. The portable electronic device as claimed in claim 10. further comprising a cover member, wherein the cover member includes a main section, and a flange extends from one end of the main section, two hooks are disposed at two sides of the main section opposite to the flange, and the pivot member defines two notches receiving the hooks.
